(19) United States
(12) Patent Application Publication
(10) Pub. No.: US 2017/0141251 A1
(43) Pub. Date: May 18, 2017

(54) MONO-BACKSHEET FOR SOLAR CELL MODULES

(71) Applicant: DSM IP Assets B.V., Heerlen (NL)

(72) Inventors: Franciscus Gerardus Henricus VAN DUIJNHOVEN, Echt (NL); Guido Jozefina Wilhelmus MEIJERS, Echt (NL)

(21) Appl. No.: 15/323,529

(22) PCT Filed: Jul. 1, 2015
(86) PCT No.: PCT/EP2015/064937

§ 371 Date: Jan. 3, 2017

(30) Foreign Application Priority Data
Jul. 4, 2014 (EP) 14175784.9

(51) Int. Cl. H01L 31/049; C08L 23/08; H01L 31/048

(52) U.S. Cl. CPC H01L 31/049; H01L 31/0481; C08L 23/0815; C08L 2203/204; C08L 2205/03

(57) ABSTRACT

The current invention relates to a solar-cell module backing monolayer obtained by melt-extruding a polymer composition comprising (a) a polyamide, (b) an elastomer and (c) an elastomer that contains groups that bond chemically and/or interact physically with the polyamide, and wherein the elastomer constitutes the continuous phase of the polymer composition and the polyamide constitutes the dispersed phase of the polymer composition, characterized in that the polymer composition comprises from 10 to 50 wt. % of the polyamide (a) and from 50 to 90 wt. % of the elastomer (b) and (c) (of the total weight of polyamide (a) and elastomer (b) and (c) present in the polymer composition).

The present invention is directed to back sheets for solar cell modules. The present invention also relates to solar cell modules comprising such back sheet. Further, the present invention relates to a polymer composition that can be used to produce back sheets for solar cell modules.

Solar cell or photovoltaic modules are used to generate electrical energy from sunlight and consist of a laminate which contains a solar cell system as the core layer. This core layer (herein also referred to as solar cell layer) is encapsulated with encapsulating materials which serve as protection against mechanical and weathering-induced influences. These encapsulating materials can consist of one or more layers of plastic films and/or plastic composites.

Because they provide a sustainable energy resource, the use of solar cells is rapidly expanding. The more traditional solar cells are the wafer-based solar cells.

Monocrystalline silicon (c-Si), poly- or multi-crystalline silicon (poly-Si or mc-Si) and ribbon silicon are the materials used most commonly in forming the more traditional wafer-based solar cells. Solar cell modules derived from wafer-based solar cells often comprise a series of self-supporting wafers (or cells) that are soldered together. The wafers generally have a thickness of between about 180 and about 240 micron. Such a panel of solar cells is called a solar cell layer and it may further comprise electrical wirings such as cross ribbons connecting the individual cell units and bus bars having one end connected to the cells and the other exiting the module. The solar cell layer is then further laminated to encapsulant layer(s) and protective layer(s) to form a weather resistant module that may be used for at least 20 years. In general, a solar cell module derived from wafer-based solar cell(s) comprises, in order of position from the front sun-facing side to the back non-sun-facing side: (1) a transparent pane (representing the front sheet), (2) a front encapsulant layer, (3) a solar cell layer, (4) a back encapsulant layer, and (5) a backing layer (or back sheet, representing the rear protective layer of the module).

The encapsulant layers used in solar cell modules are designed to encapsulate and protect the fragile solar cells. Suitable polymer materials for solar cell encapsulant layers typically possess a combination of characteristics such as high impact resistance, high penetration resistance, good ultraviolet (UV) light resistance, good long term thermal stability, adequate adhesion strength to glass and/or other rigid polymeric sheets, high moisture resistance, and good long term weatherability. Currently, ethylene/vinyl acetate copolymers are the most widely used encapsulant material and polyvinylfluoride and polyethylene terephthalate are the most widely used materials for back sheets in the industry.

When solar cell modules are used in the field, it is found that if the encapsulant sheet and the back sheet are not tightly sealed, moisture tends to enter and cause de-lamination. There is thus still a need to develop an encapsulant and backsheet material having superior adhesion to each other and therefore improve the weatherability of the solar cell module.

In contrast to the prior art, which typically provides multilayered backsheets and adhered thereto a back encapsulant layer, the object of the present invention is to identify suitable materials that can be used for producing a monolayer for a solar-cell module to be used as backing layer which backing layer is connected to the lower sides of the solar cells. In the present invention, the backing monolayer integrates the function of the back encapsulant layer and the back sheet in one layer and is to be used as rear layer for a solar-cell module.

This object has been achieved in that backing monolayer is obtained or obtainable by melt-extruding a polymer composition comprising (a) a polyamide, (b) an elastomer and (c) an elastomer that contains groups that bond chemically and/or interact physically with the polyamide, and wherein the elastomer constitutes the continuous phase of the polymer composition and the polyamide constitutes the dispersed phase of the polymer composition, characterized in that the polymer composition comprises from 10 to 50 wt. % of the polyamide (a) and from 50 to 90 wt. % of the elastomer (b) and (c) (of the total weight of polyamide (a) and elastomer (b) and (c) present in the polymer composition).

It has surprisingly been found that by melt-extruding a polymer composition as claimed a monolayer can be obtained that is applicable as rear layer for a solar-cell module and that integrates the function of a back encapsulant layer and a back sheet. The use of one layer instead of several layers has several advantages such as no delamination, more simple production of the solar-cell module as at least one layer less needs to be laminated. Further the risk that moisture and/or oxygen enters between the rear backing layer and rear encapsulant layer during the production of the solar cell module is reduced and hence the risk for delamination and/or electrical breakdown is reduced.

An elastomer is herein mentioned means a polymeric compound with a Young's modulus (measured at 23° C. according to ISO 527 1A) of from 2 MPa to 400 MPa. Preferably from 5 to 300 MPa, more preferably from 5 to 200 MPa and even more preferably from 5 to 100 MPa. An elastomer is called functionalized when it contains groups that bond chemically or interact physically with polyamide present in the polymer composition and/or with the solar cells.

The amount of groups present in the polymer composition that bond chemically and/or interact physically with the polyamide is preferably from 0.01 to 5 wt. %. The best results are generally achieved with a content of from 0.025 to 2 wt. % (of the total weight of the polymer composition), more preferably from 0.05 to 2 wt.° A.The weight ratio of non-functionalized to functionalized elastomer in the polymer composition may vary within wide limits and is determined in part by the functional groups content of the elastomer and the available reactive groups in the polyamide polymer.

The polyamide that is present in the polymer composition is preferably selected from the group consisting of polyamide-6,6, polyamide-4,6 and polyamide-6 and any mixture thereof; more preferably the polyamide is polyamide-6.

The elastomer (b) of the polymer composition is preferably a copolymer of ethylene and C3-C12-α-olefin with a density of from 0.85 to 0.93 g/cm³ and a Melt Flow Index (ASTM D1238, 190° C., 2.16 kg) of from 0.5 to 30 g/10 min. More preferably, the elastomer (b) of the polymer composition is an ethylene-octene copolymer with a density of from 0.85 to 0.93 g/cm³ and a Melt Flow Index (ASTM D1238, 190° C., 2.16 kg) of from 0.5 to 30 g/10 min. Even more preferably, said ethylene-octene copolymer is obtained by polymerization in the presence of a metallocene catalyst since it was found that this results in improved compatibility of the polyamide and the elastomer in the polymer composition.

The elastomer (c) of the polymer composition is preferably a copolymer of ethylene and C3-C12-α-olefin with a density of from 0.85 to 0.93 g/cm³ and a Melt Flow Index (ASTM D1238, 190° C., 2.16 kg) of from 0.5 to 30 g/10 min, which copolymer contains groups that bond chemically and/or interact physically with the polyamide. Preferably, the copolymer is an ethylene-octene copolymer with a density of from 0.85 to 0.93 g/cm³ and a Melt Flow Index (ASTM D1238, 190° C., 2.16 kg) of from 0.5 to 30 g/10 min. Even more preferably, said ethylene-octene copolymer is obtained by polymerization in the presence of a metallocene catalyst since this results in improved compatibility of the polyamide and the elastomer in the polymer composition. The non-functionalized elastomer and the elastomer that is functionalized may be identical or different. An example of a suitable combination is an ethylene-octene copolymer and an ethylene-octene copolymer modified with for instance maleic anhydride.

In the present invention, an elastomer that contains groups that bond chemically and/or interact physically with the polyamide is present in the polymer composition. Preferably, the polymer composition comprises functionalized elastomer (c) that contains groups that bond chemically with the polyamide. Preferably, the groups that bond chemically with the polyamide are chosen from the group consisting of anhydrides, acids, epoxides, silanes, isocyanates, oxazolines, thiols and/or (meth)acrylates, with the proviso that the combination of silane and anhydride is preferably excluded, since the presence of silanes in combination with anhydrides may result in gelation of the polymer composition. More preferably, the groups that bond chemically with the polyamide are chosen from the group consisting of unsaturated dicarboxylic acid anhydrides, unsaturated dicarboxylic acids and unsaturated dicarboxylic acid esters and mixtures of the two or more thereof. Even more preferably, the groups that bond chemically with the polyamide are chosen from the group consisting of unsaturated dicarboxylic acid anhydrides. Most preferably, the elastomer that contains groups that bond chemically with the polyamide is obtained by graft polymerizing the elastomer with maleic acid, maleic anhydride and/or fumaric acid, preferably with maleic anhydride.

Functional groups can be introduced in the elastomer in many ways. Preferred ways are by chemical modification of the elastomer or by graft polymerization of the elastomer with components containing functional groups as defined hereinabove. Non-limiting and preferred examples of such components are unsaturated dicarboxylic acid anhydrides or an unsaturated dicarboxylic acid or an ester thereof, for instance maleic anhydride, maleic acid, fumaric acid, itaconic acid and itaconic anhydride; unsaturated epoxide such as glycidyl acrylate, for example glycidyl methacrylate; and unsaturated silanes such as for example vinyltrimethoxysilane, vinyltriethoxysilane, vinyltris(beta -methoxyethoxy)silane, gamma-methacryloxypropyltrimethoxysilane, vinyltriacetoxysilane, gamma-glycidoxypropyltrimethoxysilane, gamma-glycidoxypropyltriethoxysilane, beta-(3,4-epoxycyclohexyl)ethyltrimethoxysilane, vinyltrichlorosilane or mixtures of two or more thereof.

The polymer composition used herein may further comprise one or more other polymers. Such optional polymer(s) may be present in an amount of up to about 25 wt percent, based on the total weight of the polymer composition, provided that the inclusion of such optional polymer(s) does not adversely affect the desirable performance characteristics of the polymer composition, such as the adhesion properties and the integrated function of back encapsulant layer and back sheet.

The polymer composition may further comprise additives known within the art. The first and second polymer composition preferably comprise at least one additive selected from UV stabilizers, UV absorbers, anti-oxidants, thermal stabilizers and/or hydrolysis stabilisers. When such additives stabilizers are used, the polymer composition contains from 0.05 wt. % percent to 10 wt. %, more preferably to 5 wt. %, based on the total weight of the polymer composition. Through the selection of the polyamide, the elastomer and the functional groups of the polymer composition from the described types and amounts, and the optional addition of one or more of these additives, the layer obtained by melt-extruding the first and second polymer composition fulfills all essential requirements for solar-cell module backing layer, such as weathering stability (UV and hydrolysis resistance), heat resistance, mechanical protection, electrical insulation and good adhesion.

White pigments such as TiO2, ZnO or ZnS may be added to the to monolayer to increase backscattering of sunlight leading to increased efficiency of the PV module. Black pigments such as carbon black may be added for esthetic reasons.

The thickness of the solar-cell module backing monolayer is preferably from 0.1 to 1 mm, more preferably from 0.1 to 0.8 mm, even more preferably from 0.1 to 0.75 mm.

The present invention further relates to the use of the melt-extruded sheet as described herein above as backing layer for a solar cell module, characterized in that the backing layer is the rear layer of the solar-cell module and the backing layer is connected to the lower sides of the solar cells.

The present invention further relates to a solar-cell module containing essentially, in order of position from the front-sun facing side to the back non-sun-facing side, a transparent pane, a front encapsulant layer, a solar cell layer comprised of one or more electrically interconnected solar cells, and a backing layer, wherein the backing layer is connected to the lower sides of the solar cells, characterized in that the backing layer is as defined herein above. The solar cells in the solar cell layer may be any kind of solar cells, such as thin-film solar cells (for example copper indium gallium selenide solar cells and cadmium telluride solar cells) and wafer-based solar cells.

The present invention further relates to a polymer composition comprising (a) a polyamide, (b) an elastomer and (c) an elastomer that contains groups that bond chemically and/or interact physically with the polyamide, and wherein the elastomer constitutes the continuous phase of the polymer composition and the polyamide constitutes the dispersed phase of the polymer composition, characterized in that the polymer composition comprises from 10 to 50 wt. % of the polyamide (a) and from 50 to 90 wt. % of the elastomer (b) and (c) (of the total weight of polyamide (a) and elastomer (b) and (c) present in the polymer composition). Preferred embodiments for such a polymer composition are described herein above.

The invention is now demonstrated by means of a series of examples and comparative experiments.

TABLE 1

| Materials used | Description |
|---|---|
| ICOSOLAR ® AAA 3554 | Laminate of 3 polyamide layers |
| obtained from Isovoltaic | |
| ICOSOLAR ® 2442 obtained from | Laminate of 3 layers: polyvinyl |
| Isovoltaic | fluoride-polyethylene terephtalate- |
| | polyvinyl fluoride |
| APOLHYA ® Solar R333A | Polyolefin back encapsulant- |
| obtained from Arkema | polyethylene with grafted polyamide |
| EVASKY ™ from Bridgestone | Ethylene-vinyl acetate copolymer |
| Akulon ® K122 from DSM | Polyamide-6 |
| Cupper Iodide powder obtained from | Thermal stabilizer |
| BASF | |
| Irganox ® 1098 obtained from BASF | Anti-oxidant |
| Queo ™ 8201 obtained from | LLDPE (ethylene based octene |
| Borealis Plastomers | elastomer) with density of 882 |
| | g/cm³ and MFI of 1 |
| Fusabond ® N 525 obtained | Anhydride modified ethylene |
| from DuPont | copolymer (elastomer) |
| Glass plate from Centro Solar | SECURIT EN12150 |

### Comparative Experiment A

This example is a reference and only commercial encapsulant and backsheet films were used.

A laminate was made by making the following stack: 1) ICOSOLAR® AAA 3554, 2) APOLHYA® Solar R333A, 3) one standard multi-crystalline solar cell, 4)

APOLHYA® Solar R333A, 5) glass plate of 20 by 30 cm. Lamination was done at 157 ° C. during 12 minutes.

Samples were aged in a climate chamber at 85° C. and 85% relative humidity. Samples were exposed to the damp heat test.

It was visually assessed that the sample showed no delamination during 3000 hours of ageing. It was assessed after 3000 hours of ageing, by hand, that the layer of ICOSOLAR® AAA 3554 became brittle between 2000 and 3000 hours of ageing. Flash testing did not show any significant decrease of the power output after 2000 hours of ageing.

### Comparative Experiment B

This example is a reference and only commercial encapsulant and backsheet films were used.

A laminate was made by making the following stack: 1) ICOSOLAR® AAA 3554, 2) EVASKY™, 3) one standard multi-crystalline solar cell, 4) EVASKY™ 5) glass plate of 20 by 30 cm. Lamination was done at 157° C. during 12 minutes.

Samples were aged in a climate chamber at 85 ° C. and 85% relative humidity. Samples were exposed to the damp heat test.

It was visually assessed that the sample showed no delamination during 3000 hours of ageing. It was assessed after 3000 hours of ageing, by hand, that the layer of ICOSOLAR® AAA 3554 became brittle between 2000 and 3000 hours of ageing. Flash testing did not show any significant decrease of the power output after 2000 hours of ageing.

### Comparative Experiment C

This example is a reference and only commercial encapsulant and backsheet films were used.

A laminate was made by making the following stack: 1) ICOSOLAR® 2442, 2) EVASKY™, 3) one standard multi-crystalline solar cell, 4) EVASKY™, 5) glass plate of 20 by 30 cm. Lamination was done at 157° C. during 12 minutes.

Samples were aged in a climate chamber at 85 ° C. and 85% relative humidity.

It was visually assessed that the sample showed no delamination during 3000 hours of ageing. It was assessed after 3000 hours of ageing, by hand, that the layer of ICOSOLAR® 2442 became very brittle between 2000 and 3000 hours of ageing. Flash testing did not show any significant decrease of the power output after 2000 hours of ageing.

### EXAMPLE 1

The following compound was made on a ZSK25 extruder: 25 wt % Akulon® K122, 61.85 wt % Queo™ 8201, 10 wt % Fusabond® N 525, 0.15 wt % Cupper Iodide, and 3 wt % Irganox® 1098. From the compound a 500 micrometer film was made via film-extrusion.

A laminate was made by making the following stack: 1)film of above compound, 2) one standard multi-crystalline solar cell, 3) APOLHYA® Solar R333A and 4) glass plate of 20 by 30 cm. Lamination was done at 157° C. during 12 minutes.

Samples were aged in a climate chamber at 85° C. and 85% relative humidity. Samples were exposed to the damp heat test.

It was visually assessed that the sample showed no delamination during 3000 hours of ageing. Flash testing did not show any significant decrease of the power output after 3000 hours of ageing.

### EXAMPLE 2

The following compound was made on a ZSK25 extruder: 10 wt % Akulon® K122, 76.85 wt % Queo™ 8201, 10 wt % Fusabond® N 525, 0.15 wt % Cupper Iodide, and 3 wt % Irganox® 1098. From the compound a 500 micrometer film was made via film-extrusion.

A laminate was made by making the following stack: 1)film of above compound, 2) one standard multi-crystalline solar cell, 3) APOLHYA® Solar R333A, 4) glass plate of 20 by 30 cm. Lamination was done at 157° C. during 12 minutes.

Samples were aged in a climate chamber at 85° C. and 85% relative humidity. Samples were exposed to the damp heat test.

It was visually assessed that the sample showed no delamination during 3000 hours of ageing. Flash testing did not show any significant decrease of the power output after 3000 hours of ageing.

1. A solar-cell module backing monolayer obtained by melt-extruding a polymer composition comprising (a) a polyamide, (b) an elastomer and (c) an elastomer that contains groups that bond chemically and/or interact physically with the polyamide, and wherein the elastomer constitutes the continuous phase of the polymer composition and the polyamide constitutes the dispersed phase of the polymer composition, wherein the polymer composition comprises from 10 to 50 wt. % of the polyamide (a) and from 50 to 90 wt. % of the elastomer (b) and (c) (of the total weight of polyamide (a) and elastomer (b) and (c) present in the polymer composition).

2. A backing monolayer according to claim 1, wherein the amount of groups that bond chemically or interact physically with the polyamide is from 0.025 to 2 wt. % (of the total weight of the polymer composition), preferably from 0.05 to 2 wt. %.

3. A backing monolayer according to claim 1, wherein the polyamide is selected from the group consisting of polyamide-6,6, polyamide-4,6 and polyamide-6 and any mixture thereof.

4. A backing monolayer according to claim 1, wherein the elastomer (b) is a copolymer of ethylene and C3-C12-α-olefin with a density of from 0.85 to 0.93 g/cm³ and a Melt Flow Index (ASTM D1238, 190° C., 2.16 kg) of from 0.5 to 30 g/10 min.

5. A backing monolayer according to claim 4, wherein the copolymer of ethylene and a-olefin is an ethylene-octene copolymer.

6. A backing monolayer according to claim 5, wherein the ethylene-octene copolymer is obtained by polymerization in the presence of a metallocene catalyst.

7. A backing monolayer according to claim 1, wherein the polymer composition comprises functionalized elastomer (c) that contains groups that bond chemically with the polyamide.

8. A backing monolayer according to claim 7, wherein the groups that bond chemically with the polyamide are chosen from the group consisting of anhydrides, acids, epoxides, silanes, isocyanates, oxazolines, thiols and/or (meth)acrylates.

9. A backing monolayer according to claim 7, wherein the groups that bond chemically with the polyamide are chosen from the group consisting of unsaturated dicarboxylic acid anhydrides, unsaturated dicarboxylic acids and unsaturated dicarboxylic acid esters and mixtures of the two or more thereof

10. A backing monolayer according to claim 7, wherein the groups that bond chemically with the polyamide are chosen from the group consisting of unsaturated dicarboxylic acid anhydrides.

11. A backing monolayer according to claim 7, wherein the functionalized elastomer (c) is obtained by graft polymerizing elastomer with maleic acid, maleic anhydride and/or fumaric acid.

12. A backing monolayer according to claim 1, wherein the composition further comprise at least one additive selected from UV stabilizers, UV absorbers, anti-oxidants, heat stabilizers and/or hydrolysis stabilisers.

13. Polymer composition comprising (a) a polyamide, (b) an elastomer and (c) an elastomer that contains groups that bond chemically and/or interact physically with the polyamide, and wherein the elastomer constitutes the continuous phase of the polymer composition and the polyamide constitutes the dispersed phase of the polymer composition, whereby the polymer composition comprises from 10 to 50 wt. % of the polyamide (a) and from 50 to 90 wt. % of the elastomer (b) and (c) (of the total weight of polyamide (a) and elastomer (b) and (c) present in the polymer composition, and whereby the elastomer (b) is a copolymer of ethylene and C3-C12-a-olefin with a density from 0.85 to 0.93 g/cm³ and a Melt Flow Index (ASTM D1238, density from 0.85 to 0.93 g/cm³ and a Melt Flow Index (ASTM D1238, 190° C., 2.16 kg) of from 0.5 to 30 g/10 min.

14. Polymer composition according to claim 13, wherein the copolymer of ethylene and C3-C12-α-olefin is an ethylene-octene copolymer.

15. Polymer composition according to claim 14, wherein the ethylene-octene copolymer is obtained by polymerization in the presence of a metallocene catalyst.

16. Polymer composition according to claim 13, wherein the polymer composition comprises functionalized elastomer (c) that contains groups that bond chemically with the polyamide.

17. Polymer composition according to claim 16, wherein the groups that bond chemically with the polyamide are chosen from the group consisting of anhydrides, acids, epoxides, silanes, isocyanates, oxazolines, thiols and/or (meth)acrylates.

18. Polymer composition according to claim 16, wherein the groups that bond chemically with the polyamide are chosen from the group consisting of unsaturated dicarboxylic acid anhydrides, unsaturated dicarboxylic acids and unsaturated dicarboxylic acid esters and mixtures of the two or more thereof

19. Polymer composition according to claim 16, wherein the groups that bond chemically with the polyamide are chosen from the group consisting of unsaturated dicarboxylic acid anhydrides.

20. Polymer composition according to claim 16, wherein the functionalized elastomer (c) is obtained by graft polymerizing elastomer with maleic acid, maleic anhydride and/or fumaric acid, preferably with maleic anhydride.

21. A solar-cell module containing essentially, in order of position from the front-sun facing side to the back non-sun-facing side, a transparent pane, a front encapsulant layer, a solar cell layer comprised of one or more electrically interconnected solar cells, and a backing layer, wherein the backing layer is connected to the lower sides of the solar cells, wherein the backing layer is a monolayer obtained by melt-extruding a polymer composition as claimed in claim 13.

22. A solar-cell module according to claim 21, wherein the solar cells in the solar cell layer are wafer-based solar cells.

23. Use of the melt extruded layer according to claim 1 as backing layer for a solar cell module, wherein the backing layer is the rear layer of the solar-cell module and the backing layer is connected to the lower sides of the solar cells.
